(19) United States
(12) Patent Application Publication
(10) Pub. No.: US 2026/0331363 A1
(43) Pub. Date: Oct. 22, 2026

(54) TRANSFORMER AND DISPLAY DEVICE COMPRISING SAME

(71) Applicant: LG INNOTEK CO., LTD., Seoul (KR)

(72) Inventors: Young Hwan JUNG, Seoul (KR); Ji Chang RYU, Seoul (KR); In Seong SOHN, Seoul (KR)

(21) Appl. No.: 19/114,026

(22) PCT Filed: Apr. 25, 2023
(86) PCT No.: PCT/KR2023/005587

§ 371 Date: Mar. 21, 2025

(30) Foreign Application Priority Data
Sep. 29, 2022 (KR) 10-2022-0124060

(51) Int. Cl. H01F 27/32; H01F 27/24; H05K 1/181

(52) U.S. Cl. CPC H01F 27/325; H01F 27/24; H05K 1/181; H05K 2201/1003

(57) ABSTRACT

The present invention relates to a transformer and a display device including same and, more specifically, to a transformer and a display device including same, the transformer comprising: a core portion comprising an upper core and a lower core facing the upper core in a first direction, wherein at least one of the upper core and the lower core is divided into a plurality of segment cores in a second direction intersecting the first direction; a coil portion comprising a primary coil and a secondary coil, wherein each of the primary coil and the secondary coil includes one side portion, the other side portion, and a middle portion between the one side portion and the other side portion; and a bobbin portion coupled to the core portion and the coil portion, wherein the bobbin portion comprises: a first end portion disposed in parallel with one side portion of the coil portion in the second direction; a second end portion which is located opposite the first end portion and on which the other side portion of the coil portion is disposed; and an intermediate portion which is disposed between the first end portion and the second end portion and on which the middle portion of the coil portion is disposed, and which has at least a portion that is wrapped by the plurality of segment cores.

### TECHNICAL FIELD

The present disclosure relates to a transformer and a display device including the same.

### BACKGROUND ART

In general, driving power is required in order to drive an electronic device, and a power supply device, such as a power supply unit (PSU), is essentially employed in order to supply driving power to the electronic device.

In particular, a display device, such as a flat panel TV, is required to be slim, and is continually being embodied in increasingly larger sizes. Accordingly, it is necessary to reduce the thickness of such a large-scale display while meeting the increased power requirements thereof.

In the power supply unit (PSU), a transformer occupies a relatively large volume compared to other elements. In order to realize a slim transformer, a method of omitting thick elements from the transformer or adjusting the number thereof is generally considered. For example, in recent years, a bobbin, around which a primary coil and a secondary coil are wound so as to be secured thereto, has been omitted from a transformer constituting a power supply unit of a flat panel display device, or a plurality of low-capacity slim transformers has been adopted.

In such a PSU, leakage inductance within a specific range (e.g., 50 μH or greater) is required for design of a resonant tank of a circuit and frequency matching. However, because a general slim transformer is structured such that a primary coil and a secondary coil are stacked vertically, both the primary coil and the secondary coil have an influence on the thickness of the transformer due to vertical stacking thereof. Therefore, there is a limitation in reducing the thickness of the transformer, and leakage inductance decreases greatly (e.g., about 3 μH). It is necessary to secure leakage inductance having a predetermined level or higher in order to implement a switched-mode operation in a circuit.

Therefore, there is a demand for a transformer capable of being further slimmed and securing sufficient leakage inductance and a flat panel display device using the same.

In the case of a slim transformer, a primary coil and a secondary coil are spaced horizontally from each other in order to meet leakage inductance value requirements. With increase in the size of a TV, power consumption inevitably increases, and accordingly, a spacing distance between coils or the size of a core may also increase. This causes implementation of additional adjustment of a leakage inductance value as well as deterioration in the efficiency of the transformer, deterioration in workability, and increase in manufacturing cost.

In particular, in the case of a large-capacity transformer for large TVs of 500 W (watts) or greater, the size of a core becomes greater than before, which may lead to variation in the thickness of the back surface of the core or damage to the core after heat treatment for formation of the core. This may cause heat generation during operation of the transformer, resulting in deterioration in the efficiency of the transformer. Further, additional adjustment of the leakage inductance value is required.

Therefore, it is necessary to improve the yield of the core in order to reduce the manufacturing cost thereof.

In addition, because the large-capacity transformer has a very large area, if applied thereto, a conventional slim bobbin is highly likely to be twisted or bent due to the large area of the large-capacity transformer. Moreover, in the conventional slim bobbin structure, the height of a coil is essentially increased in order to maximize the cross-sectional area of the coil. Therefore, a bobbinless structure having no upper/lower surface structure may be employed in order to realize a slim transformer. However, because such a bobbinless structure does not have a part that supports a core, a great load is applied to a bobbin.

### DISCLOSURE

### Technical Problem

A technical task of the present disclosure is to provide a transformer to which a core without any loss in the efficiency thereof is applied.

Another technical task of the present disclosure is to provide a display device to which the above transformer is applied.

The technical tasks of the present disclosure are not limited to the above-mentioned technical tasks, and other technical tasks not mentioned herein will be clearly understood by those skilled in the art from the following description.

### Technical Solution

A transformer according to the present disclosure for accomplishing the above technical tasks may include a core unit including a first core and a second core spaced apart from the first core, a coil unit including a primary coil and a secondary coil spaced apart from the primary coil, and a bobbin unit at least partially coupled to the coil unit inside the core unit, wherein each of the first core and the second core may include an upper core and a lower core disposed opposite the upper core in a first direction, each of the primary coil and the secondary coil may include one side portion, another side portion located opposite one side portion in a second direction intersecting the first direction, and a coil intermediate portion between one side portion and the other side portion, the bobbin unit may include a first end part formed to allow one side portion of the coil unit to be disposed thereon, a second end part located opposite the first end part in the second direction and formed to allow the other side portion of the coil unit to be disposed thereon, and a bobbin intermediate part disposed between the first end part and the second end part so as to allow the coil intermediate portion to be disposed thereon, and the bobbin intermediate part may be at least partially surrounded by the first core and the second core.

In addition, the bobbin unit may include a first bobbin including a first fastening portion located on the bobbin intermediate part and a second bobbin including a second fastening portion engaged with the first fastening portion and located on the bobbin intermediate part, the second bobbin being opposite the first bobbin in the second direction.

In addition, the first fastening portion and the second fastening portion may be disposed between the first core and the second core.

In addition, the first bobbin may include a coil lead-out portion formed in the first end part so as to allow at least a portion of the primary coil to be led out therethrough.

In addition, each of the first core and the second core may include a center leg portion, a first outer leg portion spaced apart from the center leg portion in a third direction intersecting each of the first and second directions, and a second outer leg portion located opposite the first outer leg portion in the third direction, with the center leg portion interposed therebetween, and each of the first bobbin and the second bobbin may include a through-hole formed therein so as to allow the center leg portion of a respective one of the first core and the second core, the first outer leg portion of a respective one of the first core and the second core, and the second outer leg portion of a respective one of the first core and the second core to pass therethrough.

In addition, the first bobbin may include a first rib disposed outside the secondary coil while extending in the second direction.

In addition, the secondary coil may be spaced apart from the primary coil in the third direction, and the second bobbin may include a 2-1^{st} rib extending from the second end part toward the first end part, the 2-1^{st} rib being disposed between the primary coil and the secondary coil, and a 2-2^{nd} rib extending from the second end part toward the first end part, the 2-2^{nd} rib being disposed outside the secondary coil.

In addition, the first bobbin may include an inner accommodation recess formed therein so as to accommodate at least a portion of the coil unit.

In addition, the bobbin unit may further include a third bobbin, and the third bobbin may include a third fastening portion engaged with the first fastening portion and the second fastening portion, one side portion at least partially inserted into the inner accommodation recess, and a seating support portion formed on one side portion so as to accommodate at least a portion of the coil unit.

In addition, the seating support portion may include a first seating portion formed to allow the primary coil to be disposed thereon and a second seating portion formed to allow the secondary coil to be disposed thereon.

In addition, the third bobbin may include a third rib extending from the third fastening portion toward the seating support portion and disposed between the primary coil and the secondary coil.

In addition, the second seating portion may include a pair of support portions protruding from side surfaces of one side portion and the other side portion of the third bobbin in a third direction intersecting each of the first direction and the second direction while being spaced apart from each other in the first direction.

In addition, the seating support portion may be at least partially disposed in the inner accommodation recess in the first bobbin.

In addition, the first rib and the 2-2^{nd} rib may at least partially overlap each other in the second direction.

In addition, the 2-1^{st} rib and the 2-2^{nd} rib may at least partially overlap each other in the third direction.

In addition, the first fastening portion, the second fastening portion, and the third fastening portion may at least partially overlap each other in the first direction.

Meanwhile, a display device including the transformer described above and a circuit board on which the transformer is disposed may be provided.

Aspects of the present disclosure are only some of the preferred embodiments of the present disclosure, and various embodiments in which the technical features of the present disclosure are reflected can be derived and understood by those skilled in the art based on the detailed description of the present disclosure to be described below.

### Advantageous Effects

The present disclosure described above has the following effects.

First, when a transformer requiring predetermined leakage inductance, such as an LLC circuit, is manufactured, it may be possible to finely adjust leakage inductance by employing separated segment cores.

In addition, it may be possible to control deterioration in the efficiency of a large-capacity transformer attributable to variation in the thickness of a core caused by increase in the size of the core.

In addition, a large-capacity transformer has problems in that a defect rate is high during the manufacturing process due to increase in the size of a core and thus mass productivity is low. However, employment of segmented cores may reduce the size of a product, thereby improving yield and reducing manufacturing cost.

In addition, due to a structure in which segmented cores are spaced apart from each other and a space therebetween is filled with a bobbin, it may be possible to prevent the core from chipping or cracking due to friction between the cores during use of the transformer.

In addition, because upper and lower surface structure of a bobbin applied to segmented cores is omitted, the overall thickness of the transformer may be reduced.

In addition, a problem of deterioration in the overall rigidity of the transformer caused by employment of segmented cores and omission of the upper/lower surface structure of the bobbin may be solved by employing a bobbin structure having ribs.

In addition, it may be possible to control a spacing distance between a primary coil and a secondary coil through ribs applied to the bobbin, thereby ensuring leakage inductance according to the spacing distance between the coils.

In addition, it may be possible to ensure unit withstand voltage of the transformer by applying an insulated coated wire to the primary coil.

In addition, because the primary coil is integrated through bonding processing, the strength of a winding form may be increased, and as a result, the overall rigidity of the transformer may be improved.

In addition, because the secondary coil is wound in a flipped state, i.e., because one end of the wire located at an inner position is placed at an outer position and the other end of the wire located at an outer position is placed at an inner position, heat generation caused by deviation in inductance may be minimized.

In addition, the flipped secondary coil may be maintained by a support portion so as not to be lifted.

In addition, because the upper portion of the bobbin unit is substituted with a thin-film-type coil fixing part, a flat panel display device including the above-described transformer may be slimmed compared to a display device including a general bobbin having an upper plate.

The effects achievable through the present disclosure are not limited to the above-mentioned effects, and other effects not mentioned herein will be clearly understood by those skilled in the art from the following description.

### DESCRIPTION OF DRAWINGS

FIG. 1 is a perspective view showing an embodiment of a transformer of the present disclosure.

FIG. 2 is an exploded perspective view of FIG. 1.

FIG. 3 is a bottom perspective view of FIG. 1.

FIG. 4 is a bottom exploded perspective view of FIG. 3.

FIG. 5A is a plan view showing a transformer including segment cores having the same size separated by the same spacing distance according to the present disclosure.

FIG. 5B is a plan view showing a transformer including segment cores having the same size separated by different spacing distances according to the present disclosure.

FIG. 5C is a plan view showing a transformer including segment cores having different sizes separated by the same spacing distance according to the present disclosure.

FIG. 5D is a plan view showing a transformer including segment cores having different sizes separated by different spacing distances according to the present disclosure.

FIG. 6 is an exploded perspective view of a bobbin unit according to the present disclosure.

FIG. 7A is a plan view showing the bobbin unit according to the present disclosure.

FIG. 7B is a cross-sectional view of portion A-A in FIG. 7A.

FIG. 7C is a cross-sectional view of portion B-B in FIG. 7A.

FIG. 7D is a cross-sectional view of portion C-C in FIG. 7A.

FIG. 8 is a perspective view showing a state in which a core unit is removed from the transformer according to the present disclosure.

FIG. 9 is a perspective view showing a state in which a first bobbin is removed from FIG. 8.

FIG. 10 is a perspective view showing a state in which a secondary coil is formed in two rows in FIG. 9.

FIG. 11 is a perspective view showing a third bobbin according to the present disclosure.

FIG. 12A is a plan view showing the shape of the secondary coil wound around a seating support portion of the first bobbin of the embodiment shown in FIG. 9 when viewed from an x-axis direction.

FIG. 12B is a view illustrating a state in which the secondary coil is disposed inside the core in the embodiment in which the secondary coil is formed in a single row.

FIG. 13A is a plan view showing the shape of the secondary coil wound around the seating support portion of the first bobbin of the embodiment shown in FIG. 10 when viewed from the x-axis direction.

FIG. 13B is a view illustrating a state in which the secondary coil is disposed inside the core in the embodiment in which the secondary coil is formed in two rows.

### BEST MODE

The present disclosure will now be described more fully hereinafter with reference to the accompanying drawings, in which various embodiments are shown. The examples, however, may be embodied in many different forms and should not be construed as being limited to the embodiments set forth herein. It is to be understood that the present disclosure covers all modifications, equivalents, and alternatives falling within the scope and spirit of the present disclosure.

While ordinal numbers including “second”, “first”, etc. may be used to describe various components, they are not intended to limit the components. These expressions are used only to distinguish one component from another component. For example, a second element could be termed a first element, and, similarly, a first element could be termed a second element, without departing from the scope of the present disclosure. As used herein, the term “and/or” includes any and all combinations of one or more of the associated listed items.

It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

In the description of the embodiments, it will be understood that when an element, such as a layer (film), a region, a pattern or a structure, is referred to as being “on” or “under” another element, such as a substrate, a layer (film), a region, a pad or a pattern, the term “on” or “under” means that the element is “directly” on or under another element or is “indirectly” formed such that an intervening element may also be present. It will also be understood that criteria of on or under is on the basis of the drawing. In addition, the thickness or size of a layer (film), a region, a pattern or a structure shown in the drawings may be exaggerated, omitted or schematically drawn for the clarity and convenience of explanation, and may not accurately reflect the actual size.

The terminology used herein is for the purpose of describing particular embodiments only and is not intended to be limiting of exemplary embodiments of the disclosure. As used herein, the singular forms are intended to include the plural forms as well, unless the context clearly indicates otherwise. It will be further understood that the term “include” or “have”, when used herein, specifies the presence of stated features, integers, steps, operations, elements, components, or combinations thereof, but do not preclude the presence or addition of one or more other features, integers, steps, operations, elements, components, or combinations thereof.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

Hereinafter, embodiments will be described in detail with reference to the accompanying drawings, and the same or equivalent elements are denoted by the same reference numerals even when they are depicted in different drawings, and redundant descriptions thereof will be omitted. In addition, the embodiments will be described using the Cartesian coordinate system, but may also be described using other coordinate systems. In the Cartesian coordinate system, the x-axis, the y-axis, and the z-axis shown in each drawing are perpendicular to each other, but the embodiments are not limited thereto. The x-axis, the y-axis, and the z-axis may intersect each other obliquely.

In addition, considering that a transformer related to the embodiments is mounted on a circuit board of a display device, the thickness (or the vertical height) of the transformer according to the present disclosure for contributing to slimness of the display device may be 14 mm or less, desirably 12 mm or less, and more desirably 10 mm or less, from the upper surface of the circuit board.

Hereinafter, a transformer to which segment cores according to the embodiments are applied will be described in detail with reference to the accompanying drawings.

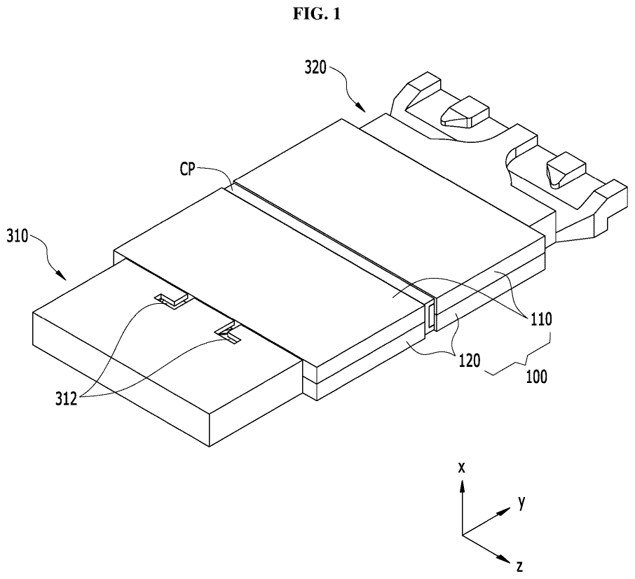

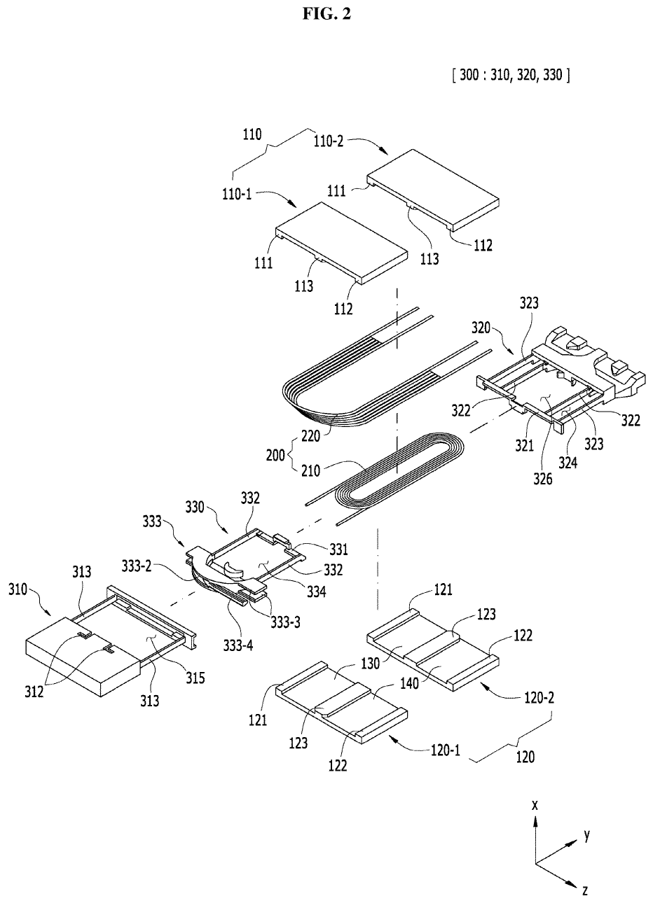

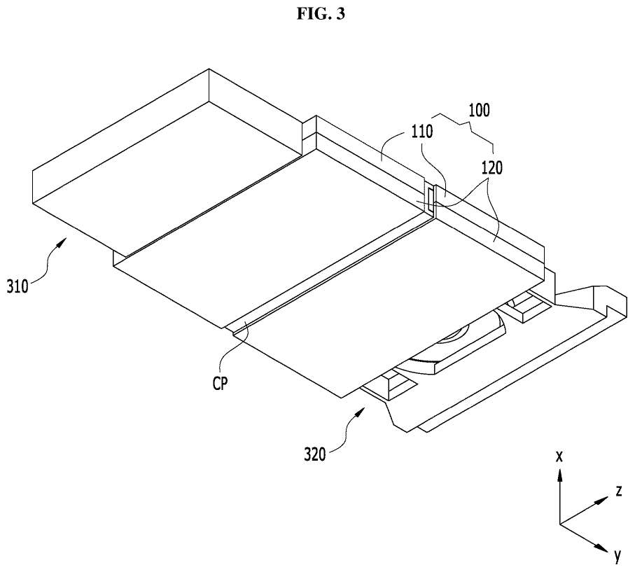

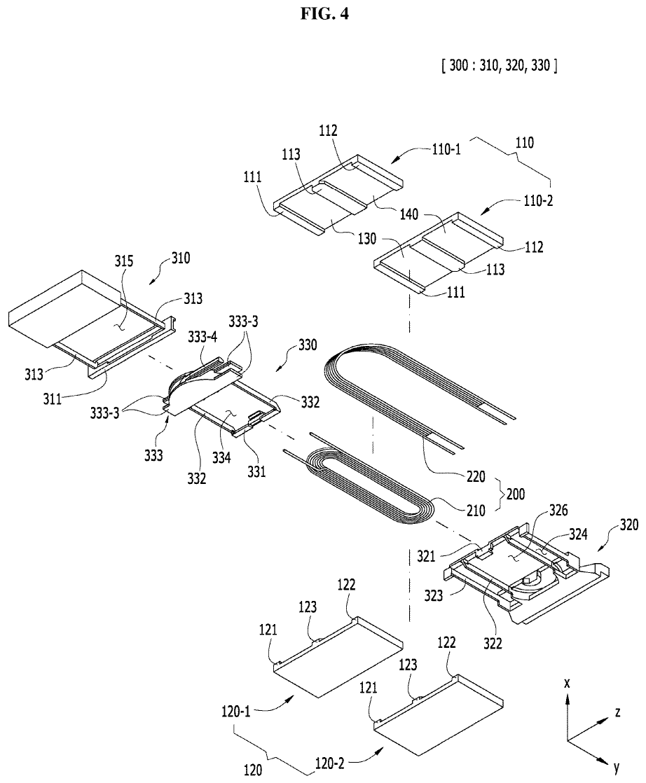

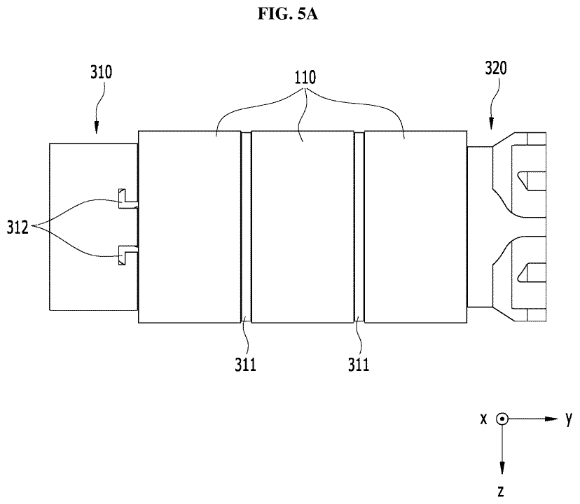

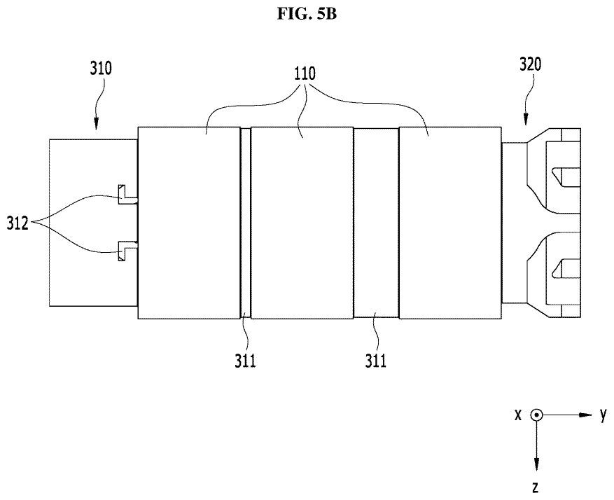

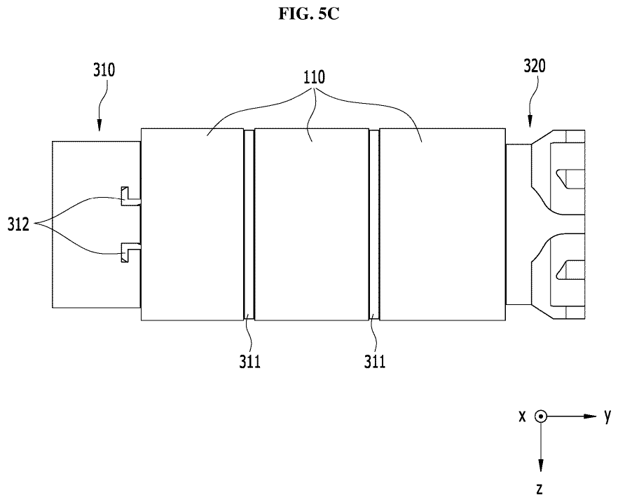

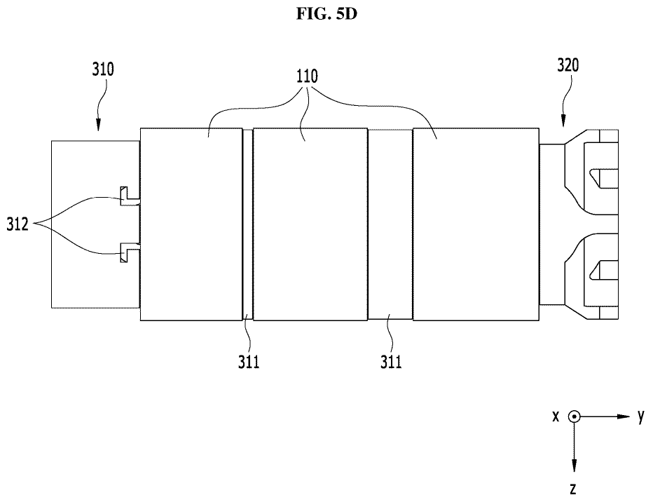

FIG. 1 is a perspective view showing an embodiment of a transformer of the present disclosure, FIG. 2 is an exploded perspective view of FIG. 1, FIG. 3 is a bottom perspective view of FIG. 1, FIG. 4 is a bottom exploded perspective view of FIG. 3, FIG. 5A is a plan view showing a transformer including segment cores separated by the same spacing distance according to the present disclosure, FIG. 5B is a plan view showing a transformer including segment cores separated by different spacing distances according to the present disclosure, FIG. 5C is a plan view showing a transformer including segment cores having different sizes separated by the same spacing distance according to the present disclosure, and FIG. 5D is a plan view showing a transformer including segment cores having different sizes separated by different spacing distances according to the present disclosure.

First, the structure of a transformer to which segment cores of the present disclosure are applied (hereinafter referred to as a “transformer”) will be described below with reference to FIGS. 1 to 5.

The transformer of the present disclosure may include a core unit 100, a coil unit 200, and a bobbin unit 300.

The core unit 100 may have the characteristics of a magnetic circuit and thus may act as a path for magnetic flux.

The core unit 100 may include an upper core 110 and a lower core 120. The upper core 110 may include a first upper core 110-1 and a second upper core 110-2, and the lower core 120 may include a first lower core 120-1 and a second lower core 120-2. In this case, the first upper core 110-1 and the first lower core 120-1 may be defined as a first core, and the second upper core 110-2 and the second lower core 120-2 may be defined as a second core. The upper core 110 and the lower core 120 may be separated from each other in a first direction (the x-axis direction), and the upper core 110 and the lower core 120 may be combined to form one core unit 100. In this case, the upper core 110 may be defined as a core located farthest from the upper surface of the above-described circuit board in the first direction, and the lower core 120 may be defined as a core located closest to the upper surface of the circuit board in the first direction. The upper core 110 and the lower core 120 may be formed to be symmetrical or asymmetrical with each other in the vertical direction, i.e., the first direction. However, for convenience of explanation, the following description will be given on the assumption that the two cores are formed to be vertically symmetrical with each other.

Each of the upper core 110 and the lower core 120 may be divided into a plurality of segment cores. That is, as shown in FIGS. 1 to 4, each of the upper core 110 and the lower core 120 may be segmented into a first core and a second core in the y-axis direction. In this case, the lengths of the first core and the second core in the y-axis direction may be the same. Here, the configuration in which the lengths of the cores in the y-axis direction are “the same” may be construed as including a configuration in which a deviation between the lengths of the cores in the y-axis direction is less than 1% taking into consideration tolerance occurring in the process such as molding or processing of the cores. Thus, the lengths of the first upper core 110-1, the second upper core 110-2, the first lower core 120-1, and the second lower core 120-2 in the y-axis direction may be the same, and the allowable deviation between the lengths in the y-axis direction may be less than 1%. In addition, as shown in FIGS. 5A to 5D, each of the upper core 110 and the lower core 120 may be divided into three segment cores. Of course, division into more than three segment cores may also be possible. Alternatively, although not shown in the drawings, only the upper core 110 may be divided into a plurality of segment cores, or only the lower core 120 may be divided into a plurality of segment cores. Alternatively, the number of segment cores of the upper core 110 and the number of segment cores of the lower core 120 may be different. Alternatively, the segment cores of each of the upper core 110 and the lower core 120 may be formed to have different sizes. Alternatively, as shown in FIGS. 5A and 5B, the segmented upper cores 110 may be formed to have the same length in the y-axis direction, or as shown in FIGS. 5C and 5D, the segmented upper cores 110 may be formed to have different lengths in the y-axis direction, and the spacing distances between the segmented upper cores 110 may be the same or different.

In this case, as shown in the drawings, the core unit 100 may be segmented in a second direction (the y-axis or z-axis direction) intersecting the first direction (the x-axis direction). Hereinafter, for convenience of description, the z-axis direction will be referred to as a third direction.

Referring again to FIGS. 1 to 4, the minimum spacing distance sd110 between the segmented upper cores 110, i.e., between the plurality of upper segment cores, may be defined as in [Equation 1] below with respect to the sum of the length of the first upper core 110-1 in the second direction and the length of the second upper core 110-2 in the second direction.

0%<sd110≤8.75% Equation 1

Here, the configuration in which the minimum spacing distance sd110 between the plurality of upper segment cores exceeds “0%” may mean a configuration in which the first upper core 110-1 and the second upper core 110-2 separated from each other are spaced apart from each other by a minimum required interval with an air gap interposed therebetween. In addition, this configuration may mean a configuration in which, as the minimum spacing distance approaches “0%”, a fastening part CP to be described later is omitted from the space between the first upper core 110-1 and the second upper core 110-2 or the fastening part is covered by the first upper core 110-1 and the second upper core 110-2 so as not to be exposed. Because the upper core 110 according to the present disclosure is implemented as segment cores, a leakage inductance value may be increased. In other words, the leakage inductance value is additionally generated from a time point at which the minimum spacing distance sd110 between the plurality of upper segment cores exceeds “0%” of the sum of the length of the first upper core 110-1 in the second direction and the length of the second upper core 110-2 in the second direction, i.e., a time point at which the first upper core 110-1 and the second upper core 110-2 are separated, and as the spacing distance increases, the leakage inductance value also increases. However, if the minimum spacing distance between the plurality of upper segment cores exceeds 8.75% of the sum of the length of the first upper core 110-1 in the second direction and the length of the second upper core 110-2 in the second direction, there is no change in the leakage inductance value, but the winding length of the coil unit 200 in the second direction increases, and accordingly, a coil resistance value, i.e., a direct current resistance (DCR) value, increases, which causes deterioration in the efficiency of the transformer.

Meanwhile, since the present disclosure has a structure in which the upper and lower surfaces of the bobbin unit are omitted, the rigidity of the bobbin may be increased through placement of a plurality of ribs to be described later. Therefore, when the structure of the fastening part CP formed by engaging end portions of the plurality of ribs is employed, the rigidity of the bobbin may be further increased. To this end, the length of the fastening part CP in the second direction, i.e., the spacing distance between the first upper core 110-1 and the second upper core 110-2, may be set to at least 0.1 mm.

In addition, the minimum spacing distance sd120 between the segmented lower cores 120, i.e., between the plurality of lower segment cores, may be defined as in [Equation 2] below with respect to the sum of the length of the first lower core 120-1 in the second direction and the length of the second lower core 120-2 in the second direction.

0%<sd120≤8.75% [Equation 2]

In addition, the lower core 120 has a structure opposite to that of the upper core 110 in the first direction. Thus, with regard to the minimum spacing distance between the plurality of lower segment cores, reference may be made to the above description of the minimum spacing distance between the upper segment cores.

Meanwhile, the minimum spacing distance between the segment cores of the upper core 110 or the lower core 120 may be set to, for example, 0.1 mm to 7 mm, and desirably 0.5 mm to 5 mm. As the spacing distance between the upper core 110 and the lower core 120 increases, the leakage inductance value increases. However, if the spacing distance exceeds 5 mm, the leakage inductance value is saturated. In addition, if the spacing distance exceeds 7 mm, the coil resistance value increases due to increase in the winding length in the second direction, leading to deterioration in the efficiency of the transformer. Thus, the spacing distance may be designed up to 7 mm. However, it is desirable that the spacing distance be set to at most 5 mm considering the leakage inductance value.

In addition, a part of the bobbin unit 300, i.e., the fastening part CP, may be disposed in the space between the upper core 110 and the lower core 120, and thus, the spacing distance between the upper core 110 and the lower core 120 may also be understood as the thickness of the fastening part CP. Therefore, in order to ensure the rigidity of the bobbin unit 300 for support of the upper core 110 and the lower core 120, it is desirable that the spacing distance between the upper core 110 and the lower core 120 be set to at least 0.5 mm. In addition, although the rigidity of the bobbin unit 300 may be ensured as the spacing distance between the upper core 110 and the lower core 120 increases, if the spacing distance exceeds 5 mm, the coil resistance value may increase due to increase in the winding length in the second direction, which may deteriorate the efficiency of the transformer.

Therefore, in order to secure the leakage inductance and to ensure the rigidity of the bobbin unit 300, it is desirable that the spacing distance between the upper core 110 and the lower core 120 be set to 0.5 mm to 5 mm.

The transformer according to the present disclosure is adapted to finely adjust the leakage inductance. As described above, the core unit 100 is implemented as a plurality of segment cores, rather than being implemented as a single core, to adjust the leakage inductance. That is, the electrical characteristics of the transformer may be finely adjusted through the spacing distance generated between the segment cores. Further, because the upper core 110 and the lower core 120 are made to have different thicknesses (lengths in at least one of the x-axis direction, the y-axis direction, or the z-axis direction), adjustment of the leakage inductance is possible. Therefore, at least one of the segmentation direction, the segmentation interval, the number of segment cores of the core unit 100, or the thickness of the core unit 100 may be adjusted depending on the required leakage inductance value. Furthermore, because the core unit 100 is manufactured so as to be segmented, when the core unit 100 is used in a large-capacity transformer adapted for, for example, large TVs, it may be possible to control heat generation attributable to variation in the shape of the core and to improve the product yield of the core.

A part of the bobbin unit 300, i.e., the fastening part CP, may be disposed between the plurality of separated segment cores. The gap between the separated segment cores may remain as an empty space. However, if the fastening part CP is disposed between the separated segment cores, it may be possible to prevent the core from chipping or cracking due to contact between the segment cores during use of the transformer. Therefore, it is desirable to place a part of the bobbin unit 300 between the separated segment cores, and, for example, the fastening part CP may be placed therebetween. Although not shown in the drawings, the fastening part CP may be divided into an upper fastening member and a lower fastening member. The upper fastening member may be disposed in an area formed by separation between the first upper core and the second upper core, and the lower fastening member may be disposed in an area formed by separation between the second lower core and the second lower core. In this case, if the number of segment cores of the upper core and the number of segment cores of the lower core are different from each other, only the upper fastening member may be disposed, or only the lower fastening member may be disposed. On the other hand, if the number of upper segment cores and the number of lower segment cores are identical to each other, it is desirable that the position of the upper fastening member and the position of the lower fastening member at least partially overlap each other in the first direction. More desirably, the width of the upper fastening member in the second direction and the width of the lower fastening member in the second direction may correspond to each other and may overlap each other in the first direction.

Referring to FIGS. 2 and 4, a first outer leg portion 111 may be disposed on one side of the upper core 110 in the third direction so as to protrude downward in the first direction and to extend in the second direction. In addition, a second outer leg portion 112 may be disposed on the opposite side of the upper core 110 in the third direction so as to protrude downward in the first direction and to extend in the second direction. In addition, a center leg portion 113 may be disposed between the first outer leg portion 111 and the second leg portion 112 so as to protrude downward in the first direction and to extend in the second direction. The first outer leg portion 111, the second outer leg portion 112, and the center leg portion 113 may be disposed parallel to each other. In addition, the widths of the first outer leg portion 111, the second outer leg portion 112, and the center leg portion 113 in the z-axis direction may be identical to or different from each other. Meanwhile, a first outer leg portion 121, a second outer leg portion 122, and a center leg portion 123 may also be disposed on the lower core 120 so as to be opposite those of the upper core 110.

The core unit 100 may further include a first space 130 and a second space 140. The first space 130 may be defined between the first outer leg portions 111 and 121 and the center leg portions 113 and 123, and may accommodate a portion of each of the coil unit 200 and the bobbin unit 300, which will be described later. The second space 140 may be defined between the second outer leg portions 112 and 122 and the center leg portions 113 and 123, and may accommodate another portion of each of the coil unit 200 and the bobbin unit 300 that is disposed opposite the portion thereof in the z-axis direction, which will be described later. Therefore, the first space 130 and the second space 140 may be formed corresponding to the thicknesses of and an interval between the portion and the other portion of each of the coil unit 200 and the bobbin unit 300 accommodated therein. The inductance of the core unit 100 may be controlled through adjustment of the sizes of the first space 130 and the second space 140, and heat generation of the transformer may be controlled according to the number of first spaces 130 and the number of second spaces 140. The core unit 100 may include a magnetic material, for example, iron or ferrite, but the disclosure is not necessarily limited thereto.

The coil unit 200 may include a primary coil 210 and a secondary coil 220. The primary coil 210 and the secondary coil 220 may have different thicknesses. In this case, each of the primary coil 210 and the secondary coil 220 may have a uniform thickness.

At least a portion of the primary coil 210 may be disposed in a donut shape inside the core unit 100. That is, as described above, the portion and the other portion of the primary coil 210 may be accommodated in the first space 130 and the second space 140. The primary coil 210 may secure unit withstand voltage of the transformer through employment of an insulated coated wire. When a magnetic component such as a transformer is developed, there are withstand voltages required for the developed unit component. Generally, required withstand voltage is higher than or equal to a certain multiple of the operating voltage of the corresponding component. Accordingly, in the case of a component in which a conventional USTC wire is wound, an insulation distance for securing withstand voltage is generated in order to satisfy withstand voltage. In this case, the insulation distance to be secured is determined in accordance with the standard. For example, if the withstand voltage required for a transformer called “A”, i.e., the withstand voltage between a primary coil and a secondary coil, is 4 kV or higher, the shortest distance between the primary coil and the secondary coil should be designed to be 4 mm or greater in order to satisfy the standard of the component. However, the components mentioned herein refer to components manufactured using USTC wires, PCBs, copper plates, or the like.

In contrast, according to the present disclosure, the surface of each wire is coated multiple times with an insulating resin so that each wire is electrically independent, thereby securing and reinforcing the withstand voltage characteristics. Although the cross-section of the insulated coated wire applied to the present disclosure is not shown in the drawings, the surface of each wire may be coated with an insulating resin in two or more layers, desirably three or more layers, thereby enhancing withstand voltage and increasing the overall strength of the winding form, with a result that the overall rigidity of the transformer may also be improved.

The secondary coil 220 may be disposed along the outer periphery of the wound primary coil 210, and the portion and the other portion thereof may be accommodated in the first space 130 and the second space 140 together with the primary coil 210. The secondary coil 220 may be formed by winding a plurality of secondary wires in a single layer or multiple layers. The secondary coil 220 may be wound in the state in which a portion thereof is flipped once, which will be described in detail later. The coil unit 200 may be wound in a donut shape on the bobbin unit 300 and may be at least partially disposed inside the core unit 100.

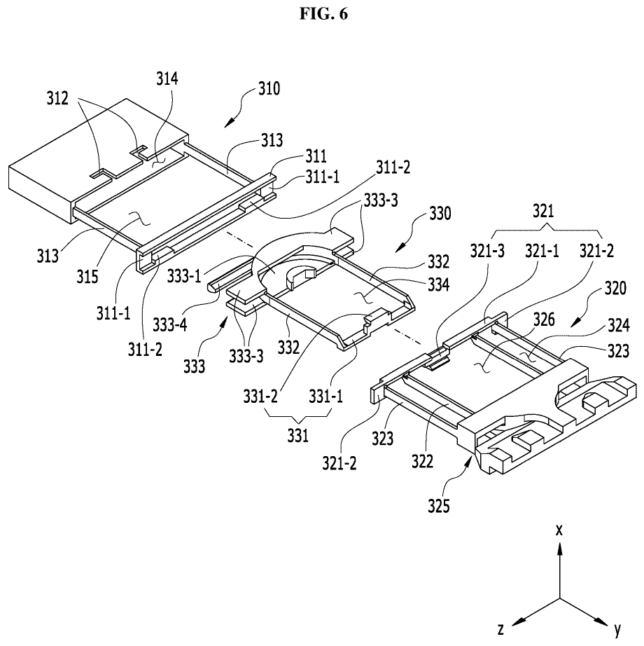

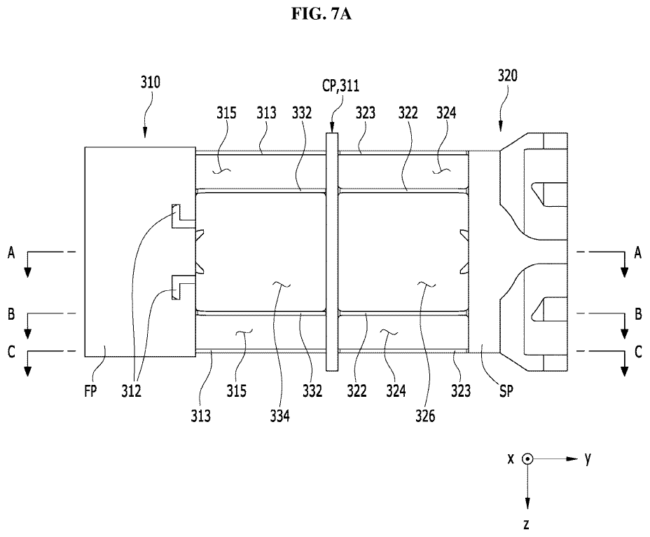

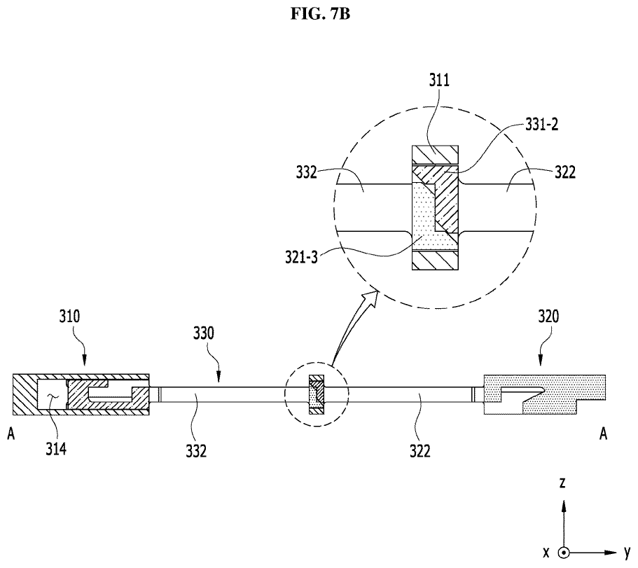

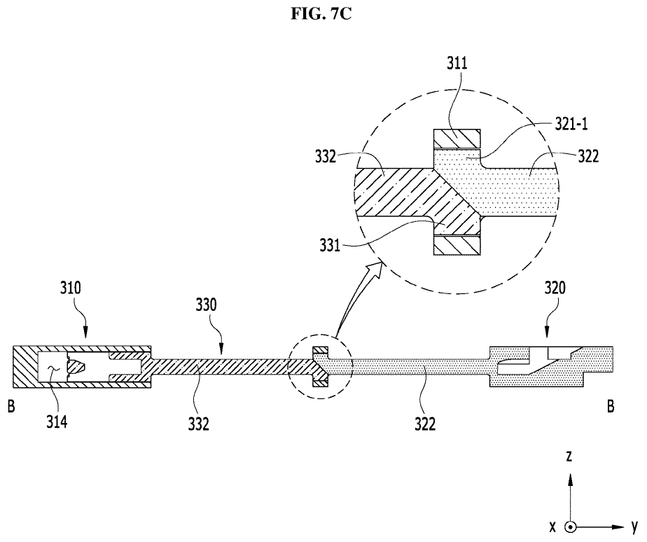

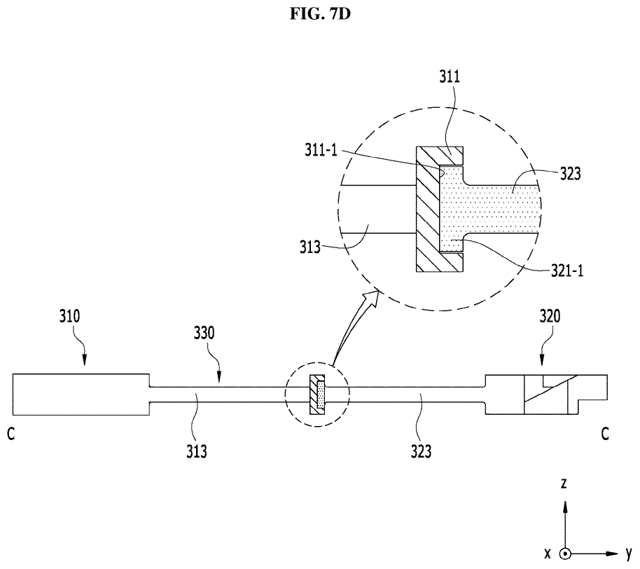

FIG. 6 is an exploded perspective view of the bobbin unit according to the present disclosure, FIG. 7A is a plan view showing the bobbin unit according to the present disclosure, FIG. 7B is a cross-sectional view of portion A-A in FIG. 7A, FIG. 7C is a cross-sectional view of portion B-B in FIG. 7A, and FIG. 7D is a cross-sectional view of portion C-C in FIG. 7A.

The bobbin unit 300 according to the present disclosure will be described with reference to FIGS. 6 and 7 (FIGS. 7A to 7D) together with FIGS. 2 and 4. For convenience of description, based on FIG. 6, the first direction will be referred to as the x-axis direction, the second direction will be referred to as the y-axis direction, the third direction will be referred to as the z-axis direction, the left-upper oblique portion in the y-axis direction will be referred to as one side or one end, and the right-lower oblique portion in the y-axis direction, opposite one side or one end, will be referred to as the other side or the other end. In addition, the portion located at an upper position in the x-axis direction will be referred to as an upper portion, an upper end, or an upper side, and the portion located at a lower position in the x-axis direction will be referred to as a lower portion, a lower end, or a lower side.

The bobbin unit 300 is a part to which the core unit 100 and the coil unit 200 are coupled. In the second direction, a first end part FP may be disposed on one side of the bobbin unit 300, a second end part SP may be disposed on the other side of the bobbin unit 300, and a bobbin intermediate part (not denoted by a reference numeral) may be disposed between the first end part FP and the second end part SP. Therefore, the remaining part, other than the first end part FP and the second end part SP, may be understood as the bobbin intermediate part. The core unit 100 may be disposed on at least a portion of the bobbin intermediate part.

The bobbin unit 300 may be provided in plural, for example, may be three in number. That is, the bobbin unit 300 may include a first bobbin 310, a second bobbin 320, and a third bobbin 330.

The first end part FP disposed on one side of the first bobbin 310 may have a rectangular parallelepiped shape and may include an inner accommodation recess 314 formed in one side thereof in the second direction. A coil lead-out portion 312 may be formed in the upper portion of the inner accommodation recess 314, i.e., the upper surface of the first end part FP in the first direction. The coil lead-out portion 312 may be provided in plural, for example, may be two in number. The coil lead-out portion 312 may be formed in a recess shape extending in a direction from the other side of the upper surface of the first end part FP toward one side thereof, and an end portion of the coil lead-out portion 312 in one side direction may be bent and extend by a predetermined length in the third direction (the z-axis direction). In the case in which two coil lead-out portions 312 are formed, the two coil lead-out portions 312 may be bent and extend by a predetermined length in opposite directions in order to secure an insulation distance between the coils led out. The coil lead-out portion 312 may facilitate lead-out and fixing of the distal end of the conductive wire constituting the primary coil 210 from and to the upper portion of the first bobbin 310 in the x-axis direction. In this case, the coil lead-out portion 312 may be described interchangeably with a first terminal portion as an area in which the distal end of the conductive wire of the primary coil 210 is disposed. In addition, the distal end of the conductive wire of the primary coil 210 having passed through the coil lead-out portion 312 may be disposed at a lower position than the maximum height of the upper core 110, thereby contributing to slimness of the transformer.

Meanwhile, the coil unit 200 may also include a first end portion, a second end portion, and a coil intermediate portion corresponding to the bobbin unit 300, and the first end part of the coil unit 200 may be inserted into and disposed in the first end part FP of the bobbin unit 300, i.e., the inner accommodation recess 314.

A first fastening member 311 may be disposed on the other side of the first bobbin 310. The first fastening member 311 may be formed in a rectangular frame shape in which two horizontal frames spaced apart from each other in the first direction and extending in the third direction and two frames connected to both end portions of each of the two horizontal frames in the first direction are coupled to each other to form a hole in the second direction. In this case, support protrusions 311-2 protruding upward may be formed on the lower portions of both inner sides of the rectangular frame. A portion of the secondary coil 220 may be seated on each of the support protrusions 311-2.

In addition, the width of the first fastening member 311 in the second direction may correspond to the width between the separated segment cores. In addition, the first fastening member 311 may include seating recesses 311-1 formed in both side portions thereof in the third direction so as to be recessed from the other side toward one side of the first fastening member in the second direction.

In addition, both sides of the inner accommodation recess 314 in the third direction and both sides of the first fastening member 311 in the third direction may be connected to each other via first ribs 313, and the vertical thickness of the first ribs 313 in the first direction may correspond to or be greater than the thickness of the coil unit 200.

The second bobbin 320 may include a second fastening member 321 formed on one side thereof and may include a coil support portion 325 into/from which the primary coil 210 and the secondary coil 220 are introduced/led out. The coil support portion 325 may be described interchangeably with a second terminal portion as an area in which the distal end of the secondary coil 220 is disposed. In this case, the other side of the primary coil 210 may be disposed below the coil support portion 325.

The second fastening member 321 may be disposed so as to be inserted into the rectangular frame of the first fastening member 311. The second fastening member 321 may include an upper frame 321-1 extending in the third direction from the upper portion in the first direction and support pieces 321-2 extending downward in the first direction from both sides of the upper frame 321-1 in the third direction. When the second fastening member 321 and the first fastening member 311 are engaged with each other, the upper frame 321-1 may be disposed on the inner upper portion of the rectangular frame, and the support pieces 321-2 may be in contact with and supported by the seating recesses 311-1.

In addition, both side portions of the coil support portion 325 in the third direction and both side portions of the second fastening member 321 in the third direction may be connected to each other via 2-2^{nd} ribs 323, and 2-1^{st} ribs 322 may be disposed so as to be spaced inward from the respective 2-2^{nd} ribs 323 by a predetermined interval in the third direction. Here, the predetermined interval may be an interval corresponding to the width of the secondary coil 220 in the third direction. The vertical thicknesses of the 2-1^{st} ribs 322 and the 2-2^{nd} ribs 323 in the first direction may also correspond to or be greater than the vertical thickness of the coil unit 200 in the first direction.

In addition, a first fastening portion 321-3 having a hook shape may be formed on the lower portion of the upper frame 321-1 so as to extend in the other side direction.

The third bobbin 330 may include a seating support portion 333 formed on one side thereof in the second direction and may include a third fastening member 331 formed on the other side thereof in the second direction. The seating support portion 333 is a portion allowing one side of the coil unit 200 in the second direction to be seated and supported thereon and then to be inserted into the inner accommodation recess 314 in the first bobbin 310. Therefore, the vertical thickness of the seating support portion 333 in the first direction may be set in consideration of the vertical length of the inner accommodation recess 314 in the first direction.

The seating support portion 333 may include a first seating portion 333-1, a second seating portion 333-2, a support portion 333-3, and a guide bar 333-4. However, the second seating portion 333-2 is not visible in FIG. 6 due to a viewing angle, and will be described with reference to FIG. 11.

The first seating portion 333-1 may be a portion on which one side of the primary coil 210 in the second direction is seated and supported while being maintained in a donut-shaped winding form and may be formed in a shape corresponding to the shape of one side of the primary coil 210.

The second seating portion 333-2 may be a portion around which one side of the secondary coil 220 in the second direction that is maintained in a winding form is wound while being in contact therewith and supported thereon. The second seating portion 333-2 may be formed to have a radius corresponding to one side of the secondary coil 220. In this case, the secondary coil 220 may be coupled to the second seating portion 333-2 in the state in which a portion thereof is flipped. The structure in which the secondary coil 220 is seated in a flipped state will be described later. The first seating portion 333-1 and the second seating portion 333-2 may be inserted into the inner accommodation recess 314 in the first bobbin 310.

At least a portion of the third fastening member 331 may be inserted into and disposed in the rectangular frame of the first fastening member 311. In this case, the third fastening member 331 may be inserted into and disposed in the rectangular frame of the first bobbin 310 in the state of being engaged with the second fastening member 321 of the second bobbin 320. That is, the third fastening member 331 may include a lower frame 331-1 extending in the third direction from the lower portion thereof in the first direction and may include a second fastening portion 331-2 that has a hook shape and extends upward from the center area of the lower frame 331-1 in the first direction and then extends toward one side of the third fastening member in the second direction. The second fastening portion 331-2 may be engaged with the first fastening portion 321-3 of the second bobbin 320 and may be disposed in the rectangular frame of the first fastening member 311. In addition, a recessed portion may be formed in the lower end of the second fastening portion 331-2. In this case, the first fastening member 311, the second fastening member 321, and the third fastening member 331 engaged with each other may form the fastening part CP. The length of the lower frame 331-1 in the third direction may correspond to an interval between the 2-1^{st} ribs 322. Third ribs 332 may be disposed between the third fastening member 331 and the seating support portion 333 so as to extend in the second direction. The third ribs 332 extending in the second direction may at least partially overlap the 2-1^{st} ribs 322 in the third direction.

When the first bobbin 310, the second bobbin 320, and the third bobbin 330 described above are coupled to each other, the bobbin unit 300 configured as shown in FIG. 7A may be formed. FIG. 7A is a view showing the configuration of the bobbin unit 300 according to the present disclosure when viewed from above.

Referring to FIG. 7A, the first end part FP of the first bobbin 310 may be disposed on one side (left) of the bobbin unit 300 according to the present disclosure in the second direction, and the second end part SP may be disposed on the other side (right) of the bobbin unit 300 in the second direction. Of course, the placement positions of the first end part FP and the second end part SP may be set to be opposite those exemplified above.

The bobbin intermediate part may be disposed between the first end part FP in which the inner accommodation recess 314 is formed and the second end part SP composed of the coil support portion 325. The bobbin intermediate part may be composed of the plurality of ribs 313, 322, 323, and 332 and the Fastening Part CP.

Although only the first fastening member 311 is shown in FIG. 7A due to a viewing angle, it is to be understood that the second fastening member 321 and the third fastening member 331 are disposed on the lower surface of the first fastening member 311 while being engaged with each other. Meanwhile, the first fastening member 311 may form the overall skeleton of the fastening part CP.

The plurality of ribs 313, 322, 323, and 332 may include the first ribs 313, the 2-1^{st} ribs 322, the 2-2^{nd} ribs 323, and the third ribs 332, and will be described with reference to FIG. 7A.

First, the first ribs 313 may extend in the y-axis direction between the first end part FP and the fastening part CP and may be disposed parallel to each other in the z-axis direction.

In addition, for convenience of description, the 2-2^{nd} ribs 323 will be described first. The 2-2^{nd} ribs 323 may extend in the y-axis direction between the second end part SP and the fastening part CP, may be disposed parallel to each other in the z-axis direction, and may at least partially overlap the first ribs 313 in the y-axis direction.

In addition, the 2-1^{st} ribs 322 may be spaced inward from the 2-2^{nd} ribs 323 by a predetermined interval in the z-axis direction so as to be parallel to the 2-2^{nd} ribs 323 and may extend in the y-axis direction between the second end part SP and the fastening part CP. In this case, the “predetermined interval” may be an interval corresponding to the width of the secondary coil 220 in the z-axis direction.

In addition, the third ribs 332 may be spaced inward from the first ribs 313 by a predetermined interval in the z-axis direction so as to be parallel to the first ribs 313 and may extend in the y-axis direction between the first end part FP and the fastening part CP. In this case, the third ribs 332 may at least partially overlap the 2-1^{st} ribs 322 in the y-axis direction.

In addition, the first ribs 313 and the third ribs 323 may at least partially overlap each other in the z-axis direction, and the 2-1^{st} ribs 322 and the 2-2^{nd} ribs 323 may at least partially overlap each other in the z-axis direction.

The plurality of ribs 313, 322, 323, and 332 described above may be disposed while forming through-holes 315, 324, 326, and 334 facing in the x-axis direction, and the first outer leg portions 111 and 121, the second outer leg portions 112 and 122, and the center leg portions 113 and 123 of the above-described core unit 100 may be disposed through the through-holes 315, 324, 326, and 334. Therefore, the first ribs 313 and the third ribs 332 of the bobbin unit 300 may be accommodated in the first space 130 in the above-described first core and may also be accommodated in the second space 140 in the first core. In addition, it is to be understood that the 2-2^{nd} ribs 323 and the 2-1^{st} ribs 322 are accommodated in the first space 130 in the second core and are also accommodated in the second space 140 in the second core.

FIGS. 7B to 7D are cross-sectional views of portions A-A, B-B, and C-C in FIG. 7A, which show the engagement state and the structure of the fastening part CP.

First, referring to FIG. 7B together with FIG. 7A, the third fastening member 331 connected to the third bobbin 330 may include a lower frame 331-1 and a second fastening portion 331-2. In addition, the second fastening member 321 connected to the second bobbin 320 may include an upper frame 321-1 and a first fastening portion 321-3. The first fastening portion 321-3 may be a recessed portion formed in the center portion of the upper frame 321-1 in the z-axis direction so as to be recessed downward in the x-axis direction, and an end portion of the recessed portion may include a shape bent toward the other side in the y-axis direction (right in FIG. 7B). The second fastening portion 331-2 may be disposed at the central portion of the lower frame 331-1 in the z-axis direction and may extend upward in the x-axis direction, and an extending end portion may include a shape bent toward one side in the y-axis direction (left in FIG. 7B). In this case, the lower end of the second fastening portion 331 may have a recessed portion formed therein in order to accommodate the end portion of the recessed portion of the first fastening portion 321-3 that is bent toward the other side in the y-axis direction (right in FIG. 7B). That is, as shown in the enlarged view in FIG. 7B, the first fastening portion 321-3 and the second fastening portion 331-2 may be in contact with and supported by each other in a complementary engagement form, and the upper and lower portions thereof in the x-axis direction may be surrounded by the first fastening member 311.

Next, referring to FIG. 7C together with FIG. 7A, one end portion of the 2-1^{st} rib 322 in the y-axis direction (left in FIG. 7C) may be formed to be inclined. In addition, the other end portion of the third rib 332 in the y-axis direction (right in FIG. 7C) may be formed to be inclined corresponding to one end portion of the 2-1^{st} rib 322 in the y-axis direction. That is, as shown in the enlarged view in FIG. 7C, the inclined surfaces of the end portions of the 2-1^{st} rib 322 and the third rib 332 may be in surface contact with each other, and the upper and lower portions thereof in the x-axis direction may be surrounded by the first fastening member 311. Of course, although not shown in the drawings, the end portions of the respective ribs may be formed to be inclined in directions opposite the inclination directions shown in FIG. 7C and may be in surface contact with each other. In this case, the 2-1^{st} rib 322 and the third rib 332 may be disposed so as to at least partially overlap each other in the y-axis direction.

In addition, referring to FIG. 7D together with FIG. 7A, the first fastening member 311 may be formed on the other end of the first rib 313 in the y-axis direction (right in FIG. 7D). A seating recess 311-1 may be formed in each of the upper and lower portions of the first fastening member 311 in the z-axis direction so as to be open toward the other side in the y-axis direction. A support piece 321-2 may be formed on each of the upper and lower portions of the 2-2^{nd} rib 323 in the z-axis direction that face toward one side in the y-axis direction (left in FIG. 7D) so as to be inserted into and supported by the seating recess 311-1.

Because the bobbin intermediate part, rather than the first end part FP and the second end part SP, forms the through-holes 315, 324, 326, and 334 facing in the x-axis direction, although upper and lower surfaces of the bobbin unit in the x-axis direction are omitted, the overall rigidity of the bobbin unit 300 according to the present disclosure may be improved and ensured due to the above-described structures of the plurality of ribs 313, 322, 323, and 332 and the fastening part CP.

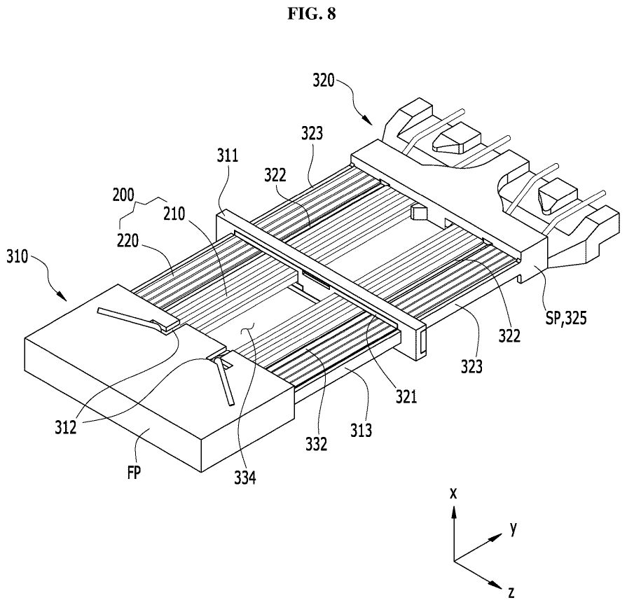

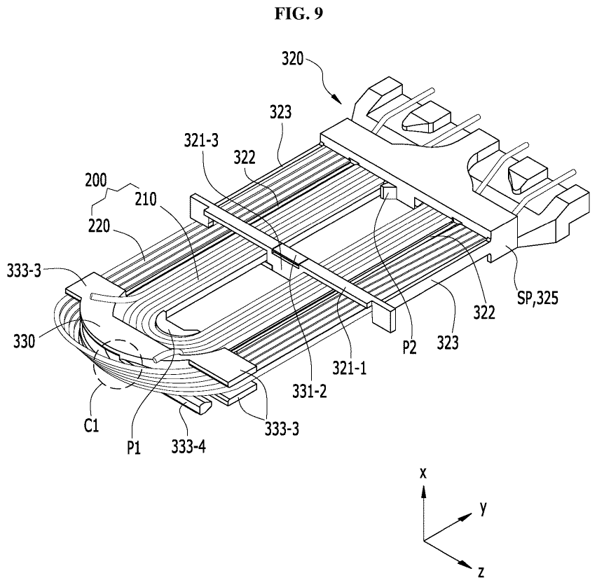

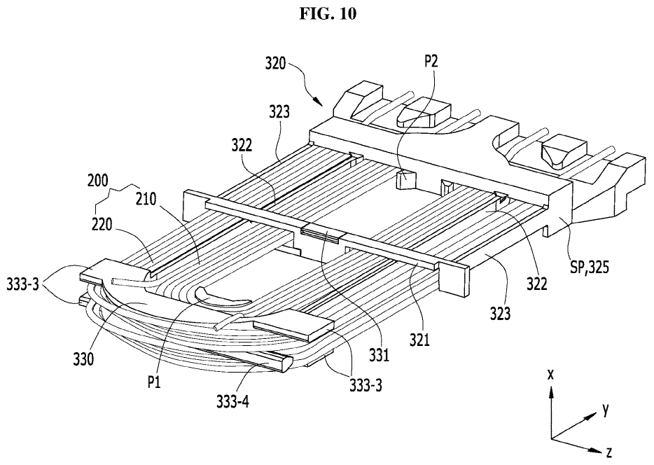

FIG. 8 is a perspective view showing a state in which the core unit is removed from the transformer according to the present disclosure, FIG. 9 is a perspective view showing a state in which the first bobbin is removed from FIG. 8, FIG. 10 is a perspective view showing a state in which the secondary coil is formed in two rows in FIG. 9, and FIG. 11 is a perspective view showing the third bobbin according to the present disclosure. FIGS. 8 to 11 are views showing the placement structure and the coupling state of the coil unit disposed on the bobbin unit applied to the present disclosure.

First, referring to FIG. 8, the coil unit 200 composed of the primary coil 210 and the secondary coil 220 may be maintained in a donut-shaped winding form. One end portion of the coil unit 200 (in the left-lower oblique direction) may be disposed on the first end part FP of the bobbin unit 300, and the other end portion of the coil unit 200 (in the right-upper oblique direction) may be disposed on the second end part SP of the bobbin unit 300. In addition, the coil intermediate portion of the coil unit 200, rather than one end portion and the other end portion of the coil unit 200, may be disposed on the bobbin intermediate part of the bobbin unit 300, i.e., in an area in which the first ribs 313, the 2-1^{st} ribs 322, the 2-2^{nd} ribs 323, and the third ribs 332 are disposed, rather than the first end part FP and the second end part SP of the bobbin unit 300. In this case, the primary coil 210 may be disposed on the bobbin unit 300 while being maintained in a donut-shaped winding form along the y-axis plane, and the secondary coil 220 may be disposed on the bobbin unit 300 while being maintained in a winding form along the outer periphery of the wound primary coil 210. That is, the primary coil 210 may be wound in a donut shape while having a width corresponding to the widths of the first fastening portion 321-3 and the second fastening portion 331-2 in the z-axis direction. Thus, one end portion of the primary coil 210 may be disposed inside the first end part FP of the bobbin unit 300, the other end portion of the primary coil 210 may be disposed inside the second end part SP of the bobbin unit 300, and the coil intermediate portion of the primary coil 210 may be disposed along the inner peripheral surfaces of the 2-1^{st} ribs 322 and the third ribs 332 in the z-axis direction. In addition, the secondary coil 220 may be disposed along the outer periphery of the wound primary coil 210. That is, one end portion of the secondary coil 220 may be disposed along the outer periphery of the primary coil 210 inside the first end part FP of the bobbin unit 300, and the coil intermediate portion of the secondary coil 220 may be disposed between the 2-1^{st} and third ribs 322 and 332, which at least partially overlap each other in the y-axis direction, and the first and 2-2^{nd} ribs 313 and 323, which at least partially overlap each other in the y-axis direction. In this case, the first and 2-2^{nd} ribs 313 and 323 may be spaced horizontally from the 2-1^{st} and third ribs 322 and 332 in the z-axis direction by a predetermined interval corresponding to or greater than the winding width of the secondary coil 220. Meanwhile, the secondary coil 220 disposed inside the second end part SP of the bobbin unit 300 may be supported and guided outside the second bobbin 320 by the coil support portion 325.

In addition, one end portion of the coil unit 200 may be inserted into the inner accommodation recess 314 in the first bobbin 310 in the state of being fitted in the seating support portion 333 of the third bobbin 330, and the inner insertion structure will be described with reference to FIG. 9.

FIG. 9 shows a state in which the first bobbin 310 is removed from FIG. 8. Prior to description of the embodiment based on FIG. 9, it will be understood that not all the related components to be described and corresponding reference numerals are shown in FIG. 9 and thus FIGS. 2 and 6 will also be referenced in the description of the embodiment. One end portion of the primary coil 210 of the above-described coil unit 200 may be seated on the first seating portion 333-1 of the seating support portion 333. A seating protrusion P1, which has a radius corresponding to the inner radius of the primary coil 210 and a width corresponding to the widths of the first fastening portion 321-3 and the second fastening portion 331-2 in the z-axis direction, may be formed on the first seating portion 333-1. In this case, a mounting protrusion P2 corresponding to the seating protrusion P1 may be formed on the lower portion of the coil support portion 325 of the second bobbin 320 in the x-axis direction. The mounting protrusion P2 may have a structure allowing the other end portion of the primary coil 210 to be fitted and mounted therein. Due to the seating protrusion P1 and the mounting protrusion P2, the wiring forms of the primary coil 210 and the secondary coil 220 may be maintained, and a short circuit between the wires thereof may be prevented.

In addition, the secondary coil 220 applied to the present disclosure may be wound along the outer periphery of the second seating portion 333-2 of the seating support portion 333 disposed on one side of the third bobbin 330 (in the left-lower oblique direction) in the state in which a portion of the secondary coil 220 is flipped once, rather than a plurality of wires of the secondary coil 220 being wound around the bobbin unit 300. That is, the portion of the secondary coil 220 located around the second seating portion 333-2 may be flipped once such that an outer wire of the secondary coil 220 is disposed at an inner portion of the secondary coil 220 and an inner wire of the secondary coil 220 is disposed at an outer portion of the secondary coil 220. In this way, because the secondary coil 220 is flipped once, a current flowing through the inner path flows to the outer path, and a current flowing through the outer path flows to the inner path. Accordingly, it may be possible to control inductance deviation caused by a difference in length between the wires. The inductance deviation generally causes heat generation during operation of the transformer. The embodiment may lower the overall temperature of the transformer. However, at the flipped point C1 of the secondary coil 220, external force may be applied to the wire, whereby, for example, a sheath may be peeled off, and withstand voltage may be reduced. Therefore, in order to solve this problem, the inner accommodation recess 314 may be formed in the first bobbin 310, and the seating support portion 333 around which one end portion of each of the primary coil 210 and the secondary coil 220 is wound may be inserted into the inner accommodation recess 314 so as not to be exposed.

In addition, the second seating portion 333-2 may include a pair of support portions 333-3 protruding in the z-axis direction from the side surfaces of one side portion and the other side portion thereof in the z-axis direction while being spaced apart from each other in the x-axis direction. The secondary coil 220 may be disposed between the support portions 333-3 spaced apart from each other. In this case, the portion of the secondary coil 220 disposed between the support portions 333-3 formed on one side portion of the second seating portion 333-2 (in the left-upper oblique direction in FIG. 9) may be flipped once, and the flipped portion of the secondary coil 220 may be guided to the support portions 333-3 formed on the other side portion of the second seating portion 333-2 while contacting the upper portion or the lower portion of the guide bar 333-4 in the x-axis direction.

In addition, as shown in FIG. 10, if the secondary coil 220 is formed in two or more rows in the x-axis direction, the above-described flipped portions of the secondary coil 220 may be separated vertically from each other and guided to the support portions 333-3 formed on the other side portion of the second seating portion 333-2 by the guide bar 333-4.

FIG. 11 is a view for understanding the structure of the support portions 333-3 and the guide bar 333-4 of the third bobbin 330. A spacing distance between the support portions 333-3 in the x-axis direction may correspond to or be greater than the thickness of the secondary coil 220 in the x-axis direction. In addition, the guide bar 333-4 may protrude in the z-axis direction from the other side portion of the second seating portion 333-2 and may extend in the winding direction of the secondary coil 220. The protruding length of the guide bar 333-4 may be less than or equal to the protruding length of the support portions 333-3 disposed at the other side portion of the second seating portion 333-2. The protruding position of the guide bar 333-4 may be disposed between the support portions 333-3 in the y-axis direction. The guide bar 333-4 may be formed in various shapes, for example, a rod shape.

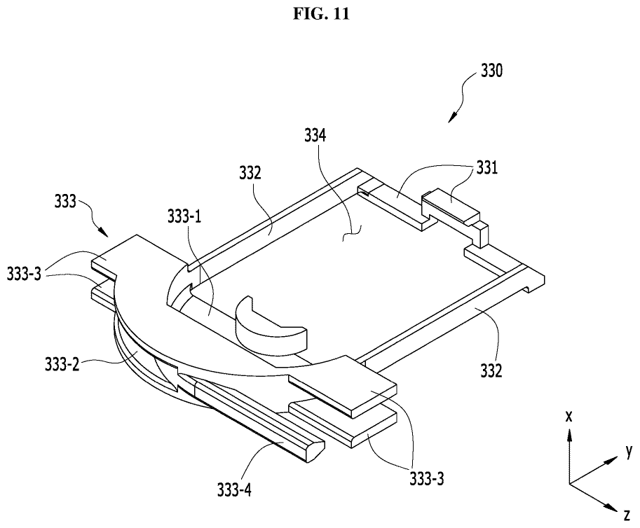

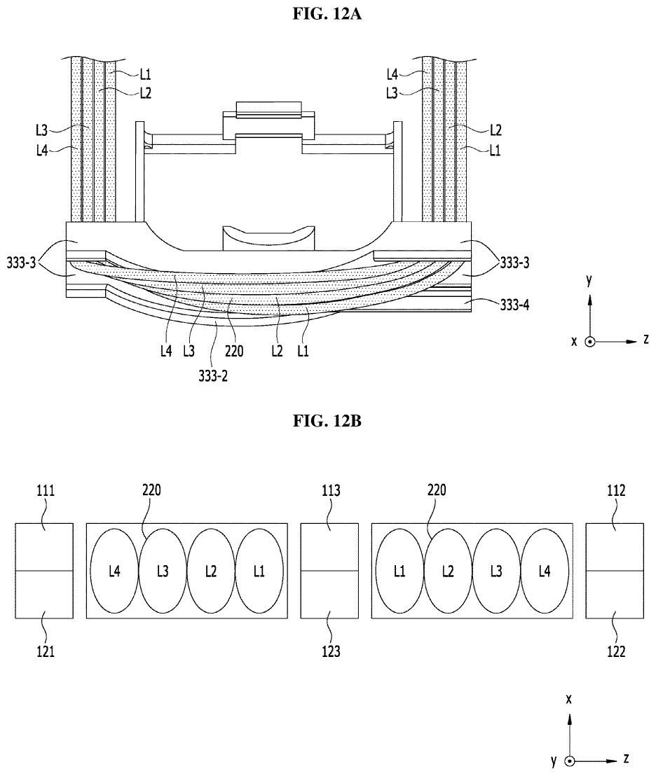

FIG. 12A is a plan view showing the shape of the secondary coil wound around the seating support portion of the first bobbin of the embodiment shown in FIG. 9 when viewed from the x-axis direction, and FIG. 12B is a view illustrating a state in which the secondary coil is disposed inside the core in the embodiment in which the secondary coil is formed in a single row.

As shown in FIG. 12A, a plurality of secondary coils L1, L2, L3, and L4 led out toward the support portions 333-2 of the first bobbin is sequentially disposed parallel to each other in the outward direction from the inner side. The portions of the secondary coils introduced between the support portions 333-3 formed on one side of the second seating portion 333-2 are flipped once outside the first bobbin, and the flipped portions of the secondary coils are introduced between the support portions 333-3 formed on the other side of the second seating portion 333-2. As shown in FIG. 12B, the plurality of secondary coils L1, L2, L3, and L4 is disposed in the order of L1, L2, L3, and L4 in the outward direction from the inner side between the first outer leg portion 111 and the center leg portion 113. In this case, the plurality of secondary coils may be bonded to each other by means of an adhesive member, thereby minimizing an air gap between the coils. The plurality of secondary coils L1, L2, L3, and L4 introduced between the support portions 333-3 formed on the other side of the second seating portion 333-2 after being flipped once outside the first bobbin is disposed in the order of L1, L2, L3, and L4 in the outward direction from the inner side. That is, unlike the related art in which the secondary coil disposed at the outermost position on one side of the bobbin is disposed at the outermost position on the other side of the bobbin in a symmetrical manner, the secondary coil disposed at the outermost position on one side of the bobbin may be disposed at the innermost position on the other side of the bobbin after being flipped once outside the bobbin. Similarly, the secondary coil disposed at the innermost position on one side of the bobbin is disposed at the outermost position on the other side of the bobbin after being flipped once outside the bobbin.

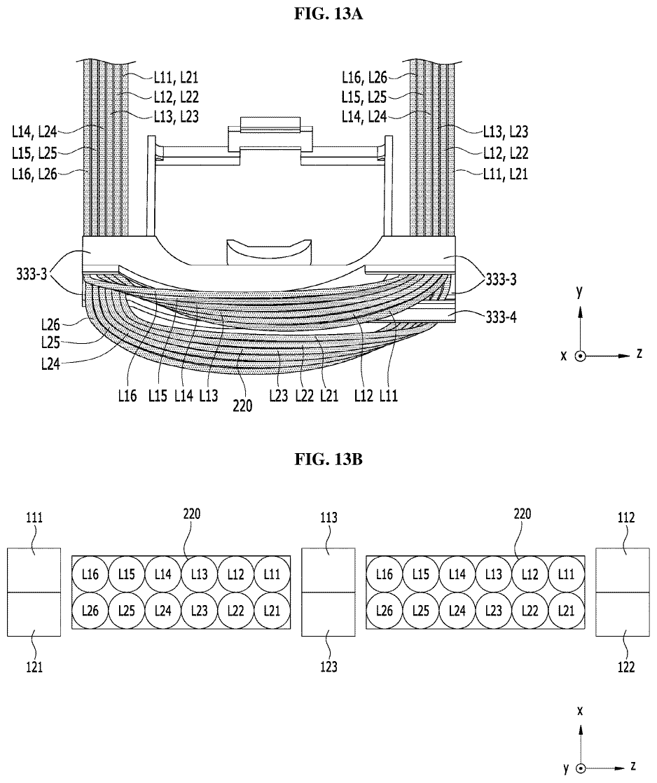

FIG. 13A is a plan view showing the shape of the secondary coil wound around the seating support portion of the first bobbin of the embodiment shown in FIG. 10 when viewed from the x-axis direction, and FIG. 13B is a view illustrating a state in which the secondary coil is disposed inside the core in the embodiment in which the secondary coil is formed in two rows. FIGS. 13A and 13B show an embodiment in which the secondary coils are arranged in two layers to form two rows.

As shown in FIG. 13A, a plurality of secondary coils L11, L21, L12, L22, L13, L23, L14, L24, L15, L25, L16, and L26 forming two layers in the first direction is sequentially disposed parallel to each other in the outward direction from the inner side on one side of the first bobbin with respect to the center of the bobbin. As shown in FIG. 13B, between the center leg portions 113 and 123 and the first outer leg portions 111 and 121, the upper coils are disposed in the order of L11, L12, L13, L14, L15, and L16 from the inner side on which the center leg portions 113 and 123 are disposed, and the lower coils are disposed in the order of L21, L22, L23, L24, L25, and L26 from the inner side on which the center leg portions 113 and 123 are disposed. The secondary coils introduced between the support portions 333-3 formed on one side of the second seating portion 333-2 are flipped once outside the first bobbin. In this case, the secondary coils are flipped in opposite directions at the upper and lower sides in the first direction. That is, the secondary coils L11 to L16 disposed on the upper side are flipped in the order of L16, L15, L14, L13, L12, and L11 from the upper side in the first direction, while the secondary coils L21 to L26 disposed on the lower side are flipped in the order of L21, L22, L23, L24, L25, and L26 from the upper side in the first direction. The upper secondary coils L11 to L16 and the lower secondary coils L21 to L26 flipped once outside the first bobbin are introduced between the support portions 333-3 formed on the other side of the second seating portion 333-2. In this case, the upper secondary coils and the lower secondary coils are separated from each other by the guide bar 333-4 protruding toward the other side of the second seating portion 333-2, and are introduced into the other side of the first bobbin. As shown in FIG. 13B, the upper secondary coils L11 to L16 introduced between the center leg portions 113 and 123 and the second outer leg portions 112 and 122 are disposed in the order of L16, L15, L14, L13, L12, and L11 from the inner side on which the center leg portions 113 and 123 are disposed, and the lower secondary coils are disposed in the order of L26, L25, L24, L23, L22, and L21 from the inner side on which the center leg portions 113 and 123 are disposed.

Meanwhile, the transformer according to the above-described embodiment may ensure a high leakage inductance value while implementing a slim structure of the bobbin unit 300, and a circuit board on which such a transformer is disposed may be applied to a display device, for example, a flat panel TV.

In addition, since inductance deviation after winding is reduced, the transformer according to the above-described embodiment may prevent a current from being concentrated on a part having a low inductance.

While the present disclosure has been particularly shown and described with reference to exemplary embodiments thereof, these embodiments are only proposed for illustrative purposes, and do not restrict the present disclosure, and it will be apparent to those skilled in the art that various changes in form and detail may be made without departing from the essential characteristics of the embodiments set forth herein. For example, respective configurations set forth in the embodiments may be modified and applied. Further, differences in such modifications and applications should be construed as falling within the scope of the present disclosure as defined by the appended claims.

### Mode for Disclosure

Various embodiments have been described in the best mode for carrying out the disclosure, and thus description thereof will be omitted.

1. A transformer, comprising:
a core unit including a first core and a second core spaced apart from the first core;
a coil unit including a primary coil and a secondary coil spaced apart from the primary coil; and
a bobbin unit at least partially coupled to the coil unit inside the core unit, wherein each of the first core and the second core includes:
an upper core; and
a lower core disposed opposite the upper core in a first direction, wherein each of the primary coil and the secondary coil includes:
one side portion;
another side portion located opposite the one side portion in a second direction intersecting the first direction; and
a coil intermediate portion between the one side portion and the other side portion,
wherein the bobbin unit includes:
a first end part formed to allow the one side portion of the coil unit to be disposed thereon;
a second end part located opposite the first end part in the second direction and formed to allow the other side portion of the coil unit to be disposed thereon; and
a bobbin intermediate part disposed between the first end part and the second end part so as to allow the coil intermediate portion to be disposed thereon, and
wherein the bobbin intermediate part is at least partially surrounded by the first core and the second core.

2. The transformer according to claim 1, wherein the bobbin unit includes:
a first bobbin including a first fastening portion located on the bobbin intermediate part; and
a second bobbin including a second fastening portion engaged with the first fastening portion and located on the bobbin intermediate part, the second bobbin being opposite the first bobbin in the second direction.

3. The transformer according to claim 2, wherein the first fastening portion and the second fastening portion are disposed between the first core and the second core.

4. The transformer according to claim 3, wherein the first bobbin includes a coil lead-out portion formed in the first end part so as to allow at least a portion of the primary coil to be led out therethrough.

5. The transformer according to claim 4, wherein each of the first core and the second core includes:
a center leg portion;
a first outer leg portion spaced apart from the center leg portion in a third direction intersecting each of the first and second directions; and
a second outer leg portion located opposite the first outer leg portion in the third direction, with the center leg portion interposed therebetween, and
wherein each of the first bobbin and the second bobbin includes a through-hole formed therein so as to allow the center leg portion of a respective one of the first core and the second core, the first outer leg portion of a respective one of the first core and the second core, and the second outer leg portion of a respective one of the first core and the second core to pass therethrough.

6. The transformer according to claim 5, wherein the first bobbin includes a first rib disposed outside the secondary coil while extending in the second direction.

7. The transformer according to claim 6, wherein the secondary coil is spaced apart from the primary coil in the third direction, and wherein the second bobbin includes:
a 2-1^{st} rib extending from the second end part toward the first end part, the 2-1^{st} rib being disposed between the primary coil and the secondary coil; and
a 2-2^{nd} rib extending from the second end part toward the first end part, the 2-2^{nd} rib being disposed outside the secondary coil.

8. The transformer according to claim 7, wherein the first bobbin includes an inner accommodation recess formed therein so as to accommodate at least a portion of the coil unit.

9. The transformer according to claim 8, wherein the bobbin unit further includes a third bobbin, and
wherein the third bobbin includes:
a third fastening portion engaged with the first fastening portion and the second fastening portion;
one side portion at least partially inserted into the inner accommodation recess; and
a seating support portion formed on the one side portion so as to accommodate at least a portion of the coil unit.

10. The transformer according to claim 9, wherein the seating support portion includes:
a first seating portion formed to allow the primary coil to be disposed thereon; and
a second seating portion formed to allow the secondary coil to be disposed thereon.

11. The transformer according to claim 10, wherein the third bobbin includes a third rib extending from the third fastening portion toward the seating support portion and disposed between the primary coil and the secondary coil.

12. The transformer according to claim 11, wherein the second seating portion includes a pair of support portions protruding from side surfaces of one side portion and the other side portion of the third bobbin in a third direction intersecting each of the first direction and the second direction while being spaced apart from each other in the first direction.

13. The transformer according to claim 12, wherein the seating support portion is at least partially disposed in the inner accommodation recess in the first bobbin.

14. The transformer according to claim 13, wherein the first rib and the 2-2^{nd} rib at least partially overlap each other in the second direction.

15. The transformer according to claim 14, wherein the 2-1^{st} rib and the 2-2^{nd} rib at least partially overlap each other in the third direction.

16. The transformer according to claim 13, wherein the first fastening portion, the second fastening portion, and the third fastening portion at least partially overlap each other in the first direction.

17. A transformer, comprising:
a core unit including a first core and a second core spaced apart from the first core;
a coil unit including a primary coil and a secondary coil spaced apart from the primary coil; and
a bobbin unit at least partially coupled to the coil unit inside the core unit,
wherein each of the primary coil and the secondary coil includes:
one side portion;
another side portion located opposite the one side portion in a second direction intersecting the first direction; and
a coil intermediate portion between the one side portion and the other side portion,
wherein the bobbin unit includes:
a first end part formed to allow the one side portion of the coil unit to be disposed thereon;
a second end part located opposite the first end part in the second direction and formed to allow the other side portion of the coil unit to be disposed thereon; and
a bobbin intermediate part disposed between the first end part and the second end part so as to allow the coil intermediate portion to be disposed thereon, and
wherein the bobbin intermediate part is at least partially surrounded by the first core and the second core,
wherein the bobbin unit includes:
a first bobbin including a first fastening portion located on the bobbin intermediate part; and
a second bobbin including a second fastening portion located on the bobbin intermediate part,
wherein the first fastening portion and the second fastening portion are engaged with each other, and
wherein the second bobbin is opposite the first bobbin in the second direction.

18. The transformer according to claim 17, wherein the first fastening portion and the second fastening portion are disposed between the first core and the second core.

19. The transformer according to claim 18, wherein the first bobbin includes a coil lead-out portion formed in the first end part so as to allow at least a portion of the primary coil to be led out therethrough.

20. A display device, comprising:
the transformer according to claim 1; and
a circuit board on which the transformer is disposed.
